(19) United States
(12) Patent Application Publication
(10) Pub. No.: US 2008/0067334 A1
(43) Pub. Date: Mar. 20, 2008

(54) Image sensor package structure and method for manufacturing the same

(76) Inventors: Jason Chuang, Hsinchu Hsien (TW); Mon Nan Ho, Hsinchu Hsien (TW); Hsiu Wen Tu, Hsinchu Hsien (TW); Chen Pin Peng, Hsinchu Hsien (TW); Chung Hsien Hsin, Hsinchu Hsien (TW); Wei Chang, Hsinchu Hsien (TW)

Correspondence Address: PRO-TECHTOR INTERNATIONAL SERVICES, 20775 NORADA CT., SARATOGA, CA, 95070, US

(21) Appl. No.: 11/986,227

(22) Filed: Nov. 19, 2007

Related U.S. Application Data
(63) Continuation-in-part of application No. 11/404,730, filed on Apr. 14, 2006.

(51) Int. Cl. H01J 5/02; H01L 21/64

(52) U.S. Cl. 250/239; 438/106; 257/E21.001

(57) ABSTRACT

An image sensor package structure includes a substrate, a chip, a plurality of wires, and a frame layer. The substrate has an upper surface, which is formed with first electrodes, and a lower surface, which is formed with second electrodes corresponding to electrically connect to the first electrodes. The chip has a sensor region and a plurality of bonding pads located at the side of the sensor region of the chip, and is mounted on the upper surface of the substrate. The plurality of wires are electrically connected the bonding pads of the chip to the first electrodes of the substrate. The frame layer is inserted with a transparent layer, and is arranged on the upper surface of the substrate to cover the chip.

The is a continuation-in-part application of applicant's U.S. patent application Ser. No. 11/404,730, filed on Apr. 14, 2006.

### BACKGROUND OF THE INVENTION

1. Field of the Invention

2. Description of the Related Art

Referring to FIG. 1, it is an image sensor structure includes a substrate 10, frame layer 18, a chip 26, a plurality of wires 28, and a transparent layer 3.

The substrate 10 has an first surface 12 on which plurality of first electrodes 15 are formed, and a second surface 14 on which plurality of second electrodes 16 are formed, the first electrodes 15 are corresponding to electrically connect to the second electrodes 16.

The frame layer 18 has a upper surface 20 and a lower surface 22, the lower surface 22 of the frame layer 18 is adhered on the first surface 22 of the substrate 10 to form a cavity 24.

The chip 26 is arranged on the first surface 12 of the substrate 10, and is located within the cavity 24, and is formed with bonding pads 27.

The wire 28 has a first end 30 and a second end 32, the first end 30 is electrically connected the bonding pad 27 of the chip 26, the second end 30 is electrically connected the first electrodes 15 of the substrate 10.

The transparent layer 34 is adhered on the upper surface 20 of the frame layer 18.

### SUMMARY OF THE INVENTION

An objective of the invention is to provide an image sensor package structure and method for manufacturing the same, and capable of decreasing the size of the package.

To achieve the above-mentioned object, the invention includes a substrate, a chip, a plurality of wires, and a frame layer. The substrate has an upper surface, which is formed with first electrodes, and a lower surface, which is formed with second electrodes corresponding to electrically connect to the first electrodes. The chip has a sensor region and a plurality of bonding pads located at the side of the sensor region of the chip, and is mounted on the upper surface of the substrate. The plurality of wires are electrically connected the bonding pads of the chip to the first electrodes of the substrate. The frame layer is inserted with a transparent layer, and is arranged on the upper surface of the substrate to cover the chip.

### BRIEF DESCRIPTION OF THE DRAWINGS

FIG. 1 is a schematic illustration showing a conventional image sensor package structure.

FIG. 2 is a cross-sectional schematic illustration showing an image sensor package of the present invention.

FIG. 3 is second schematic illustration showing an image sensor package structure of the present invention.

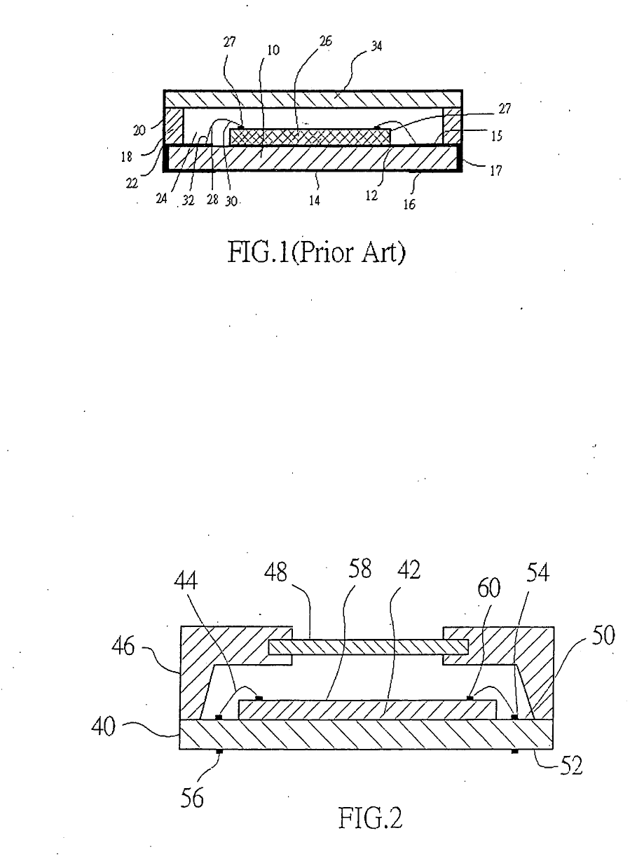

### DETAILED DESCRIPTION OF THE INVENTION

Please refer to FIG. 2, an image sensor package structure includes a substrate 40, a chip 42, wires 44, a frame layer 46, and a transparent layer 48.

The substrate 40 has an upper surface 50, which is formed with a first electrodes 54, and a lower surface 52, which is formed with second electrodes 56 corresponding to electrically connect to the first electrodes 54.

The chip 42 has a sensor region 58 and a plurality of bonding pads 60 located at the side of the sensor region 58 of the chip 42, and is mounted on the upper surface 50 of the substrate 40.

The plurality of wires 44 are electrically connected the bonding pads 60 of the chip 42 to the first electrodes 54 of the substrate 40.

The frame layer 46 is inserted with a transparent layer 48, and is arranged on the upper surface 50 of the substrate 40 to cover the chip 42.

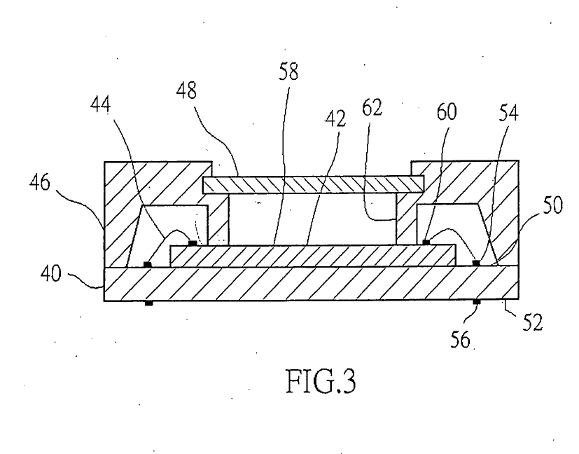

Please refer to FIG. 3, the frame layer is formed with a protection layer 62, and is located under the transparent layer 48 to surround the sensor region 58 of the chip 42.

Please refer to FIG. 2, the method for manufacturing an image sensor package structure includes the step of:

Providing a substrate 40 has an upper surface 50, which is formed with a first electrodes 54, and a lower surface 52, which is formed with second electrodes 56 corresponding to electrically connect to the first electrodes 54.

Providing a chip 42 has a sensor region 58 and a plurality of bonding pads 60 located at the side of the sensor region 58 of the chip 42, and is mounted on the upper surface 50 of the substrate 40.

Providing a plurality of wires 44 are electrically connected the bonding pads 60 of the chip 42 to the first electrodes 54 of the substrate 40.

Providing a frame layer 46 is inserted with a transparent layer 48, and is arranged on the upper surface 50 of the substrate 40 to cover the chip 42. The frame layer 46 is formed with a protection layer 62, and is located under the transparent layer 48 to surround the sensor region 58 of the chip 42.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. An image sensor package structure, the package comprising:
a substrate having an upper surface, which is formed with first electrodes, and a lower surface, which is formed with second electrodes corresponding to electrically connect to the first electrodes;
a chip having a sensor region and a plurality of bonding pads located at the side of the sensor region of the chip, and mounted on the upper surface of the substrate;
a plurality of wires electrically connected the bonding pads of the chip to the first electrodes of the substrate; and
a frame layer inserted with a transparent layer, and arranged on the upper surface of the substrate to cover the chip, and formed with a protection layer located under the transparent layer to surround the sensor region of the chip.

2. A method for manufacturing an image sensor package structure, comprising the steps of:
providing a substrate having an upper surface, which is formed with first electrodes, and a lower surface, which is formed with second electrodes corresponding to electrically connect to the first electrodes;
providing a chip having a sensor region and a plurality of bonding pads located at the side of the sensor region of the chip, and mounted on the upper surface of the substrate;
providing a plurality of wires electrically connected the bonding pads of the chip to the first electrodes of the substrate; and
providing a frame layer inserted with a transparent layer, and arranged on the upper surface of the substrate to cover the chip, and formed with a protection layer located under the transparent layer to surround the sensor region of the chip.
